(19) United States
(12) Patent Application Publication
(10) Pub. No.: US 2025/0056955 A1
(43) Pub. Date: Feb. 13, 2025

(54) DISPLAY DEVICE

(71) Applicant: LG DISPLAY CO., LTD., Seoul (KR)

(72) Inventors: Won Joung KIM, Paju-si (KR); Yeon Jun YOO, Paju-si (KR)

(73) Assignee: LG DISPLAY CO., LTD., Seoul (KR)

(21) Appl. No.: 18/796,629

(22) Filed: Aug. 7, 2024

(30) Foreign Application Priority Data
Aug. 11, 2023 (KR) 10-2023-0105413

(51) Int. Cl. H01L 27/15

(52) U.S. Cl. CPC H01L 27/156

(57) ABSTRACT

A display device may include a display region and a non-display region disposed on a substrate, a pixel including a plurality of sub-pixels disposed in the display region, and a power line disposed between each of sub-pixels. A light-emitting element may be disposed on the power line, and the light-emitting element may be electrically connected to a first connection electrode. Each sub-pixel may include a plurality of transistors, and a second connection electrode may be connected to a driving transistor among the plurality of transistors.

### CROSS-REFERENCE TO RELATED APPLICATIONS

This application claims the benefit of and priority to Korean Patent Application No. 2023-0105413, filed on Aug. 11, 2023, the entire contents of which are incorporated herein by reference for all purposes.

### BACKGROUND

### 1. Technical Field

The present disclosure relates to a display device, and more particularly to, for example, without limitation, a display device using a light-emitting diode (LED).

### 2. Discussion of the Related Art

Display devices used in computer monitors, televisions (TVs), mobile phones, and the like include an organic light-emitting display (OLED) device which emits light by itself and the like and a liquid crystal display (LCD) device which requires a separate light source and the like.

The scope of application of the display devices is becoming more diverse, including not only computer monitors and TVs but also personal portable devices, and research on display devices having large display areas and having reduced volumes and weights is being conducted.

Further, recently, display devices including light-emitting diodes (LEDs) have been attracting attention as next-generation display devices. Since LEDs are formed of inorganic materials rather than organic materials, LEDs are highly reliable and has a longer lifespan than liquid crystal display devices or organic light-emitting display devices. Further, LEDs not only have a fast lighting speed, but also have excellent light-emitting efficiency, excellent impact resistance, excellent stability, and can display high luminance images.

The description of the related art should not be assumed to be prior art merely because it is mentioned in or associated with this section. The description of the related art includes information that describes one or more aspects of the subject technology, and the description in this section does not limit the invention.

### SUMMARY

One or more aspects of the present disclosure are directed to providing a display device including a transparent electrode which may facilitate the detection of defects in transistors and repair of the transistors.

One or more aspects of the present disclosure are directed to providing a display device capable of improving light-emitting efficiency without additionally disposing a reflective electrode.

The technical problems of the present disclosure are not limited to the above-mentioned technical problems, and other technical problems which are not mentioned will be clearly understood by those skilled in the art from the following description.

According to an aspect of the present disclosure, there is provided a display device comprising a display region and a non-display region disposed on a substrate, a pixel including a plurality of sub-pixels disposed in the display region, and a power line disposed between each of the plurality of sub-pixels, wherein a light-emitting element is disposed on the power line, the light-emitting element is for being electrically connected to a first connection electrode, each sub-pixel of the plurality of sub-pixels includes a plurality of transistors, and a second connection electrode is connected to a driving transistor among the plurality of transistors.

According to another aspect of the present disclosure, there is provided a display device comprising a substrate, a display region, and a non-display region, wherein the display region includes a light-emitting region and a non-light-emitting region, a transistor is disposed in the non-light-emitting region, a power line is disposed in the light-emitting region and the non-light-emitting region, a first electrode is disposed on the transistor and the power line, a light-emitting element is disposed on the first electrode, and the light-emitting element overlaps the power line.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a schematic configuration diagram of a display device according to one example embodiment of the present disclosure;

FIG. 2A is a partial cross-sectional view of the display device according to one example embodiment of the present disclosure;

FIG. 2B is a perspective view of a tiling display device according to one example embodiment of the present disclosure;

FIG. 3 is a plan view of a display panel of the display device according to one example embodiment of the present disclosure;

FIGS. 4A to 4D are plan views of a pixel region of the display device according to one example embodiment of the present disclosure; and

FIG. 5 is a cross-sectional view of the display device according to one example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure and a method of achieving the same should become clear with embodiments described in detail below with reference to the accompanying drawings. However, the present disclosure is not limited to the embodiments disclosed below and may be implemented with a variety of different forms. The present embodiments are merely provided to allow those skilled in the art to completely understand the scope of the present disclosure, and the present disclosure is defined only by the scope of the claims.

The figures, dimensions, ratios, angles, numbers, and the like disclosed in the drawings for describing the embodiments of the present disclosure are merely illustrative and are not limited to matters shown in the present disclosure. Further, in describing the present disclosure, detailed descriptions of well-known technologies will be omitted when it is determined that they may unnecessarily obscure the gist of the present disclosure.

Terms such as “comprising,” “including,” “having,” and “composed of” used herein are intended to allow other elements to be added unless the terms are used with the term “only.” When a component is expressed in the singular form, it may include a case in which the plural form is included unless otherwise explicitly stated.

Components are interpreted as including an ordinary error range even when not expressly stated.

For the description of a positional relationship, for example, when the positional relationship between two parts is described as “on,” “above,” “below,” “next to,” and the like, one or more parts may be interposed therebetween unless the term “immediately” or “directly” is used in the expression.

When an element or layer is disposed “on” another element or layer, the element is disposed directly on another element or layer or disposed on another element another layer with still another element therebetween.

In addition, the terms “first,” “second,” and the like may be used herein to describe various components, the components are not limited by the terms. These terms are used only to distinguish one component from another. Accordingly, a first component discussed below could be termed a second component without departing from the teachings of the present disclosure.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

Like reference numerals generally denote like elements throughout the specification.

The size and thickness of each component illustrated in the drawings are shown for convenience of description, and the present disclosure is not necessarily limited to the size and thickness of the component illustrated.

The features of various embodiments of the present disclosure may be partially or entirely bonded to or combined with each other. The embodiments may be interoperated and performed in various ways technically and may be carried out independently of or in association with each other.

Hereinafter, an example of a display device according to the present disclosure will be described in detail with reference to the accompanying drawings. In adding reference numerals to components in each drawing, the same components may have the same reference numerals as much as possible even though they are indicated on different drawings.

Hereinafter, the present disclosure will be described with reference to the drawings.

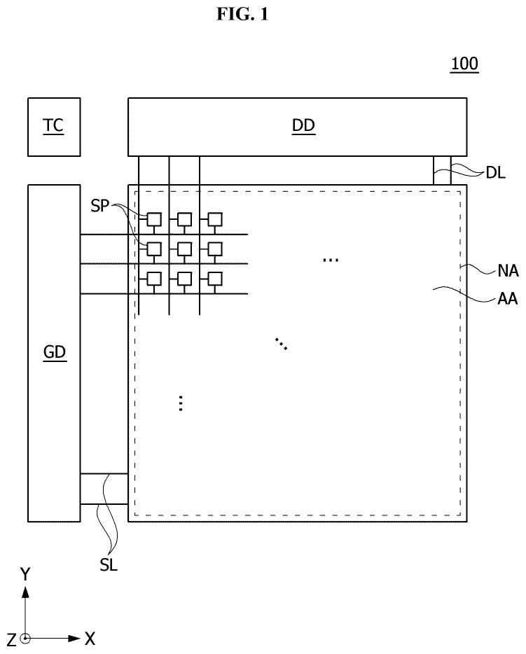

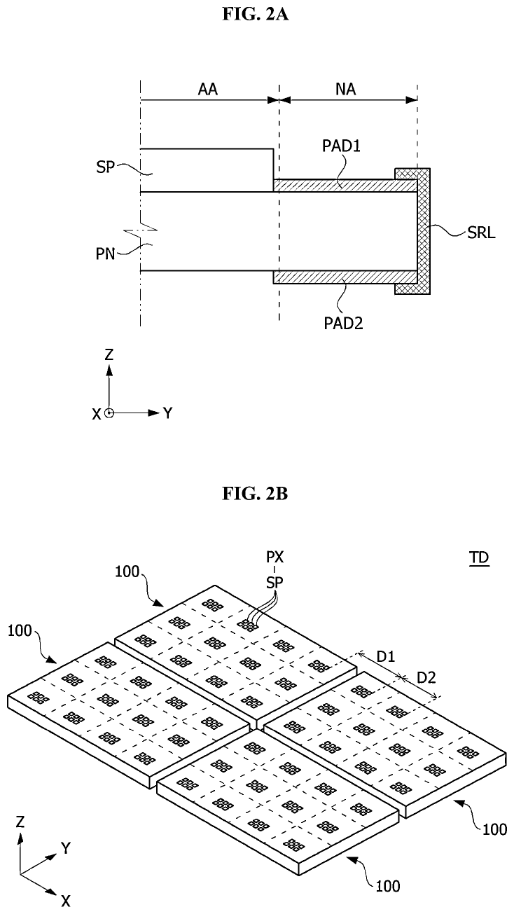

FIG. 1 is a schematic configuration diagram of a display device according to one example embodiment of the present disclosure. FIG. 2A is a partial cross-sectional view of the display device according to one example embodiment of the present disclosure. FIG. 2B is a perspective view of a tiling display device according to one example embodiment of the present disclosure. For convenience of description, FIG. 1 schematically illustrates only a display panel PN, a gate driver GD, a data driver DD, and a timing controller TC among various components of the display device.

Referring to FIG. 1, the display device includes a display panel PN including a plurality of sub-pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. In FIG. 1, one gate driver GD is shown as being disposed spaced apart from one side of the display panel PN, but the number and disposition of gate drivers GD are not limited thereto.

The data driver DD converts image data input from the timing controller TC to a data voltage using a reference gamma voltage according to a plurality of data control signals provided from the timing controller TC. The data driver DD may supply the converted data voltage to a plurality of data lines DL.

The timing controller TC aligns image data input from the outside and supplies the image data to the data driver DD. The timing controller TC may generate gate control signals and data control signals using synchronization signals input from the outside, for example, a dot clock signal, a data enable signal, and a horizontal/vertical synchronization signal. Further, the timing controller TC may control the gate driver GD and the data driver DD by respectively supplying the generated gate control signals and data control signals to the gate driver GD and the data driver DD.

The display panel PN is a configuration for displaying an image to a user and includes a plurality of sub-pixels SP. In the display panel PN, the plurality of scan lines SL and the plurality of data lines DL cross each other, and each of the plurality of sub-pixels SP is connected to the scan line SL and the data line DL. Further, although not shown in the drawings, each of the plurality of sub-pixels SP may be connected to a high-potential power line, a low-potential power line, a reference line, and the like.

A display region AA and a non-display region NA surrounding the display region AA may be defined in the display panel PN.

The display region AA is a region where an image is displayed in the display device. The plurality of sub-pixels SP of a plurality of pixels PX and a circuit for driving the plurality of sub-pixels SP may be disposed in the display region AA. The plurality of sub-pixels SP are minimum units constituting the display region AA, and n sub-pixels SP may form one pixel PX. A light-emitting element and a thin film transistor for driving the light-emitting element may be disposed in each of the plurality of sub-pixels SP. A plurality of light-emitting elements may be defined differently according to the type of display panel PN. For example, when the display panel PN is an inorganic light-emitting display panel, the light-emitting element may be a light-emitting diode (LED) or a micro light-emitting diode (micro-LED).

A plurality of lines which transmit various signals to the plurality of sub-pixels SP are disposed in the display region AA. For example, the plurality of lines may include the plurality of data lines DL which respectively supply the data voltage to the plurality of sub-pixels SP, the plurality of scan line SL which respectively supply the scan signals to the plurality of sub-pixels SP, and the like. The plurality of scan lines SL may extend in one direction in the display region AA and may be connected to the plurality of sub-pixels SP, and the plurality of data lines DL may extend in a direction different from the one direction in the display region AA and may be connected to the plurality of sub-pixels SP. Further, the low-potential power line, the high-potential power line, and the like may be further disposed in the display region AA, but the present disclosure is not limited thereto.

The non-display region NA is a region where an image is not displayed and may be defined as a region extending from the display region AA. In the non-display region NA, link lines and pad electrodes for transmitting signals to the sub-pixels SP of the display region AA, driver integrated circuits (ICs) such as a gate driver IC and a data driver IC, or the like may be disposed.

However, the non-display region NA may be located on a rear surface of the display panel PN, that is, on a surface without sub-pixels SP, or may be omitted, but is not limited to what is shown in the drawings.

Meanwhile, drivers such as the gate driver GD, the data driver DD, and the timing controller TC may be connected to the display panel PN in various ways. For example, the gate driver GD may be mounted in the non-display region NA in a gate in panel (GIP) manner, or may be mounted between the plurality of sub-pixels SP in the display region AA in a gate in active area (GIA) manner. For example, the data driver DD and the timing controller TC may be formed on a separate flexible film and printed circuit board, and the data driver GD and the timing controller TC may be electrically connected to the display panel by bonding the flexible film and the printed circuit board to the pad electrodes formed in the non-display region NA of the display panel PN.

When the gate driver GD is mounted in a GIP manner and the data driver DD and the timing controller TC transmit the signals to the display panel PN through the pad electrodes in the non-display region NA, an area of the non-display region NA for disposing the gate driver GD and the pad electrodes needs to exceed a certain level, and accordingly, a bezel may increase.

On the other hand, when the gate driver GD is mounted inside the display region AA in a GIA manner, and a side line SRL which connects the signal lines on the front side of the display panel PN to the pad electrodes on the rear surface of the display panel PN is formed to bond the flexible film and the printed circuit board to the rear surface of the display panel PN, the non-display region NA on the front side of the display panel PN may be reduced to a minimum size. That is, when the gate driver GD, the data driver DD, and the timing controller TC are connected to the display panel PN in the above-described manner, it may be possible to implement a zero bezel where there is substantially no bezel.

Specifically, referring to FIGS. 2A and 2B, a plurality of pad electrodes for transmitting various signals to the plurality of sub-pixels SP are disposed in the non-display region NA of the display panel PN. For example, a plurality of first pad electrodes PAD1 which transmit signals to the plurality of sub-pixels SP are disposed in the non-display region NA on the front side of the display panel PN, and a plurality of second pad electrodes PAD2 electrically connected to driving components such as the flexible film and the printed circuit board are disposed in the non-display region NA on the rear surface of the display panel PN. That is, only a pad region where the first pad electrodes PAD1 are disposed may be minimally formed in the non-display region NA on the front side of the display panel PN where an image is displayed.

In this case, although not shown in the drawings, various signal lines connected to the plurality of sub-pixels SP, for example, the scan lines SL, the data lines DL, or the like may extend from the display region AA to the non-display region NA and may be electrically connected to the first pad electrodes PAD1.

Further, the side line SRL is disposed along a side surface of the display panel PN. The side line SRL may electrically connect the first pad electrodes PAD1 on the front side of the display panel PN and the second pad electrodes PAD2 on the rear surface of the display panel PN. Accordingly, signals may be transmitted from driving components on the rear surface of the display panel PN to the plurality of sub-pixels SP through the second pad electrodes PAD2, the side line SRL, and the first pad electrodes PAD1. Accordingly, the area of the non-display region NA on the front side of the display panel PN may be minimized by forming a signal transmission path between the front, side, and rear surface of the display panel PN.

Further, referring to FIG. 2B, a tiling display device TD having a large screen may be implemented by connecting a plurality of display devices 100. In this case, when the tiling display device TD is implemented using the display device 100 having a minimized bezel as shown in FIG. 2A, a seam region between the display devices 100 where no image is displayed may be minimized and thus display quality may be improved.

For example, a plurality of sub-pixels SP may form one pixel PX, and a first distance D1 between the outermost pixel PX of one display device 100 and the outermost pixel PX of another display device 100 adjacent thereto may be implemented to be the same as a second distance D2 between the pixels PX in one display device 100. Accordingly, since the distances D1 and D2 of the pixels PX between the display devices 100 may be configured to be constant, the seam region may be minimized.

However, FIGS. 2A and 2B illustrate examples, and the display device 100 according to one example embodiment of the present disclosure may be a general display device in which a bezel is present, but is not limited thereto.

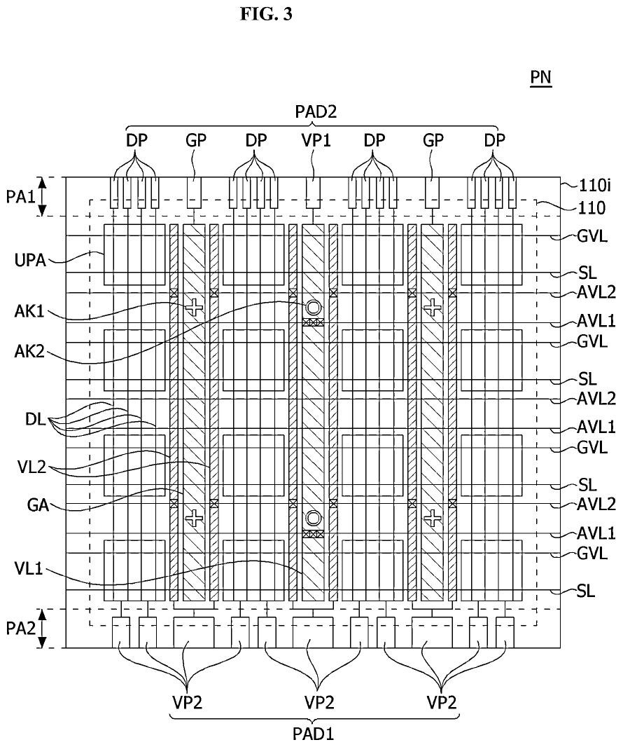

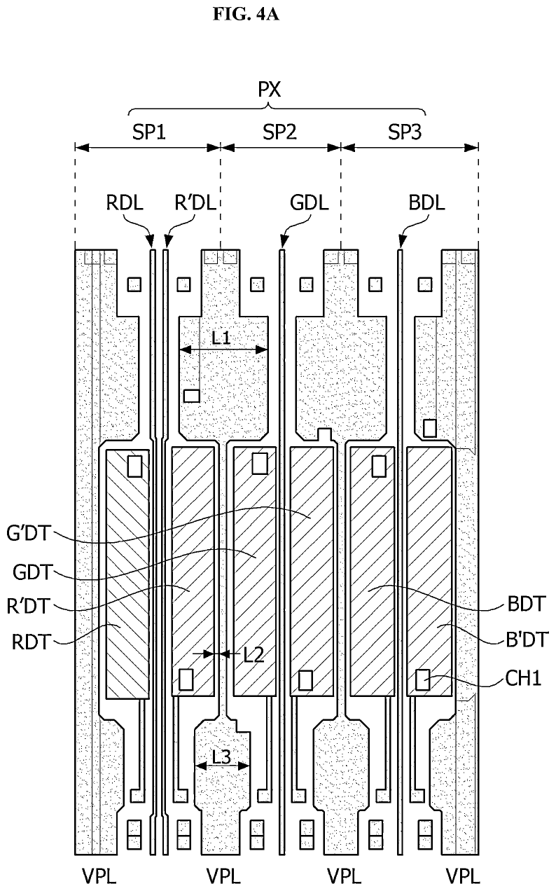

FIG. 3 is a plan view of the display panel of the display device according to one example embodiment of the present disclosure.

Referring to FIG. 3, the display panel PN may display an image by forming a plurality of pixels PX on an insulating substrate. For example, the insulating substrate may be formed of glass or resin, and may be formed by including a polymer or plastic. Further, the insulating substrate may be formed of a plastic material having flexibility.

A plurality of pixel regions UPA, a plurality of gate driving regions GA, and a plurality of pad regions PA1 and PA2 of the insulating substrate are disposed. Among the above, the plurality of pixel regions UPA and the plurality of gate driving regions GA may be included in the display region AA of the display panel PN.

First, the plurality of pixel regions UPA are regions where the plurality of pixels PX are disposed. The plurality of pixel regions UPA may be disposed to form a plurality of rows and a plurality of columns. Each of the plurality of pixels PX disposed in the plurality of pixel regions UPA includes a plurality of sub-pixels SP. Each of the plurality of sub-pixels SP may independently emit light by including a light-emitting element and a pixel circuit.

The plurality of gate driving regions GA are regions where the gate driver GD is disposed. The gate driver GD may be mounted in the display region AA in a gate in active area (GIA) manner. For example, the gate driving regions GA may be formed along a row direction and/or a column direction between the plurality of pixel regions UPA. The gate driver GD formed in the gate driving regions GA may provide scan signals to the plurality of scan lines SL.

The gate driver GD disposed in the gate driving regions GA may include a circuit for outputting scan signals. In this case, the gate driver GD may include, for example, a plurality of transistors and/or a plurality of capacitors. Here, active layers of the plurality of transistors may be formed of a semiconductor material such as an oxide semiconductor, amorphous silicon, polysilicon, or the like, but are not limited thereto. In this case, the active layers of the plurality of transistors may be formed of the same material or may be formed of different materials. Further, the active layers of the transistors of the gate driver may be formed of the same material as or a different material from active layers of various transistors of the pixel circuit.

The plurality of pad regions are regions where the plurality of first pad electrodes PAD1 are disposed. The plurality of first pad electrodes PAD1 may transmit various signals to various lines extending in the column direction in the display region AA. For example, the plurality of first pad electrodes PAD1 include data pads DP which transmit a data voltage to the data lines DL, gate pads GP which transmit clock signals, start signals, a gate-low voltage, a gate-high voltage, and the like for driving the gate driver GD to the gate driver GD, a high-potential power pad VP1 which transmits a high-potential power voltage to a high-potential power line VL1, and low-potential power pads VP2 which transmit a low-potential power voltage to low-potential power lines VL2.

The plurality of pad regions include a first pad region PA1 located at an upper edge of the display panel PN and a second pad region PA2 located at a lower edge of the display panel PN. In this case, different types of first pad electrodes PAD1 may be disposed in the first pad region PA1 and the second pad region PA2. For example, the data pads DP, the gate pads GP, and the high-potential power pad VP1 among the plurality of first pad electrodes PAD1 may be disposed in the first pad region PA1, and the low-potential power pads VP2 may be disposed in the second pad region PA2.

In this case, the plurality of first pad electrodes PAD1 may be respectively formed in different sizes. For example, a plurality of data pads DP connected to the plurality of data lines DL in a one-to-one manner may have a relatively narrow width, and the high-potential power pad VP1, the low-potential power pads VP2, and the gate pads GP may have relatively wide widths. However, the widths of the data pads DP, the gate pads GP, the high-potential power pad VP1, and the low-potential power pads VP2 shown in FIG. 3 are examples, and sizes of the first pad electrodes PAD1 may be variously configured, but are not limited thereto.

Meanwhile, in order to reduce the bezel of the display panel PN, edges of the display panel PN may be cut and removed. A bezel region may be decreased by forming the plurality of pixels PX, the plurality of lines, and the plurality of first pad electrodes PAD1 on an initial first substrate 110i which is an insulating substrate, and grinding edge portions of the initial first substrate 110i. In the grinding process, since a portion of the initial first substrate 110i may be removed, a first substrate 110 having a relatively smaller size may be formed. In this case, portions of the plurality of first pad electrodes PAD1 and the lines disposed at edges of the first substrate 110 may be removed. Accordingly, only portions of the plurality of first pad electrodes PAD1 may remain on the first substrate 110.

Next, a plurality of data lines DL extending in the column direction from the plurality of first pad electrodes PAD1 are disposed on the first substrate 110 of the display panel PN. The plurality of data lines DL may extend toward the plurality of pixel regions UPA from the plurality of data pads DP of the first pad region PA1. The plurality of data lines DL may extend in the column direction and may be disposed to overlap the plurality of pixel regions UPA. Accordingly, the plurality of data lines DL may respectively transmit a data voltage to pixel circuits of the plurality of sub-pixels SP.

A plurality of high-potential power lines VL1 extending in the column direction are disposed on the first substrate 110 of the display panel PN. Some of the plurality of high-potential power lines VL1 may extend toward the plurality of pixel regions UPA from the high-potential power pad VP1 of the first pad region PA1, and transmit a high-potential power voltage to the light-emitting elements of each of the plurality of sub-pixels SP. Further, another part of the plurality of high-potential power lines VL1 may be electrically connected to other high-potential power lines VL1 through auxiliary high-potential power lines AVL1 to be described below. In FIG. 3, for convenience of description, one high-potential power line VL1 and one high-potential power pad VP1 are illustrated as being disposed, but a plurality of high-potential power lines VL1 and a plurality of high-potential power pads VP1 may be disposed.

A plurality of low-potential power lines VL2 extending in the column direction are disposed on the first substrate 110 of the display panel PN. At least some of the plurality of low-potential power lines VL2 may extend toward the plurality of pixel regions UPA from the low-potential power pads VP2 of the second pad region PA2, and respectively transmit a low-potential power voltage to the pixel circuits of the plurality of sub-pixels SP. Further, another part of the plurality of low-potential power lines VL2 may be electrically connected to other low-potential power lines VL2 through auxiliary low-potential power lines AVL2 to be described below.

A plurality of scan lines SL extending in the row direction are disposed on the first substrate 110 of the display panel PN. The plurality of scan lines SL may extend in the row direction, and may be disposed across the plurality of pixel regions UPA and the plurality of gate driving regions GA. The plurality of scan lines SL may transmit scan signals to the pixel circuits of the plurality of sub-pixels SP from the gate driver GD.

A plurality of auxiliary high-potential power lines AVL1 extending in the row direction are disposed on the first substrate 110 of the display panel PN. The plurality of auxiliary high-potential power lines AVL1 may be disposed in regions between the plurality of pixel regions UPA. The plurality of auxiliary high-potential power lines AVL1 extending in the row direction may be electrically connected to the plurality of high-potential power lines VL1 extending in the column direction through contact holes and form a mesh structure. Accordingly, the plurality of auxiliary high-potential power lines AVL1 and the plurality of high-potential power lines VL1 are configured to form a mesh structure, and thus may minimize a voltage drop and a voltage deviation.

A plurality of auxiliary low-potential power lines AVL2 extending in the row direction are disposed on the first substrate 110 of the display panel PN. The plurality of auxiliary low-potential power lines AVL2 may be disposed in regions between the plurality of pixel regions UPA. The plurality of auxiliary low-potential power lines AVL2 extending in the row direction may be electrically connected to the plurality of low-potential power lines VL2 extending in the column direction through contact holes and form a mesh structure. Accordingly, the plurality of auxiliary low-potential power lines AVL2 and the plurality of low-potential power lines VL2 are configured to form a mesh structure, and thus may lower the resistance of the lines and minimize a voltage deviation.

A plurality of gate driving lines GVL extending in the row direction and the column direction are disposed on the first substrate 110 of the display panel PN. Some gate driving lines GVL among the plurality of gate driving lines GVL may extend to the gate driving regions GA from the gate pads GP of the first pad region PA1 and transmit signals to the gate driver GD. Another part among the plurality of gate driving lines GVL may extend in the row direction and transmit signals to the gate driver GD of the gate driving regions GA. Accordingly, since various signals are transmitted from the gate driving lines GVL to the gate driver GD, the gate driver GD may be driven.

The plurality of gate driving lines GVL may include lines which transmit clock signals, start signals, a gate-low voltage, a gate-high voltage, and the like to the gate driver GD. Accordingly, since various signals are transmitted from the gate driving lines GVL to the gate driver GD, the gate driver GD may be driven.

A plurality of align keys AK1 and AK2 are disposed in regions between the plurality of pixel regions UPA in the display panel PN. The plurality of align keys AK1 and AK2 are used for alignment in a manufacturing process of the display panel PN. The plurality of align keys AK1 and AK2 include first align keys AK1 and second align keys AK2.

The first align keys AK1 may be disposed in the gate driving regions GA among the regions between the plurality of pixel regions UPA. The first align keys AK1 may be used to check the alignment positions of a plurality of light-emitting elements 130. For example, the first align keys AK1 may have a cross shape, but are not limited thereto.

The second align keys AK2 may be disposed to overlap the high-potential power lines VL1 among the regions between the plurality of pixel regions UPA. Since holes overlapping the second align keys AK2 are formed in the high-potential power lines VL1, the second align keys AK2 and the high-potential power lines VL1 may be distinguished. The second align keys AK2 may be used to align the display panel PN and a donor. The display panel PN and the donor may be aligned using the second align keys AK2, and the plurality of light-emitting elements 130 of the donor may be transferred to the display panel PN. For example, the second align keys AK2 may have a circular ring shape, but are not limited thereto.

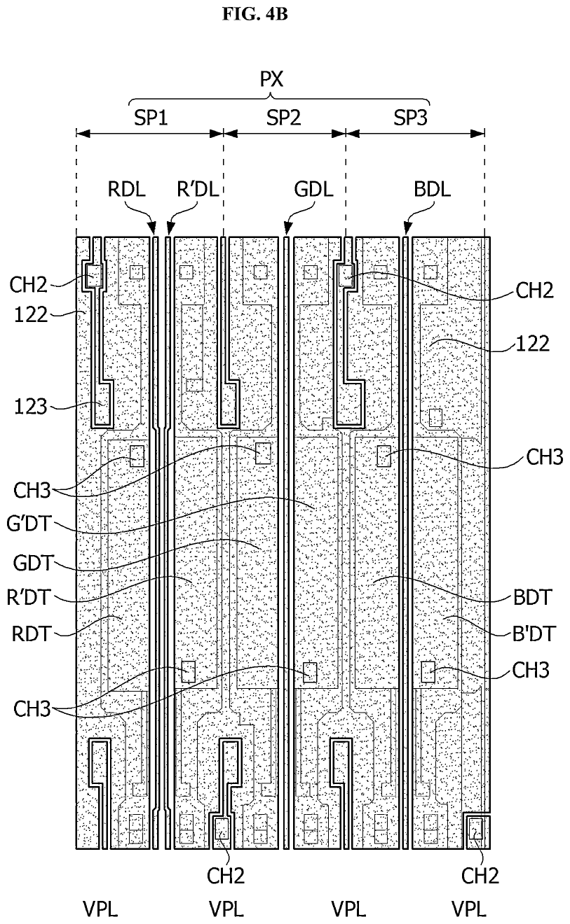

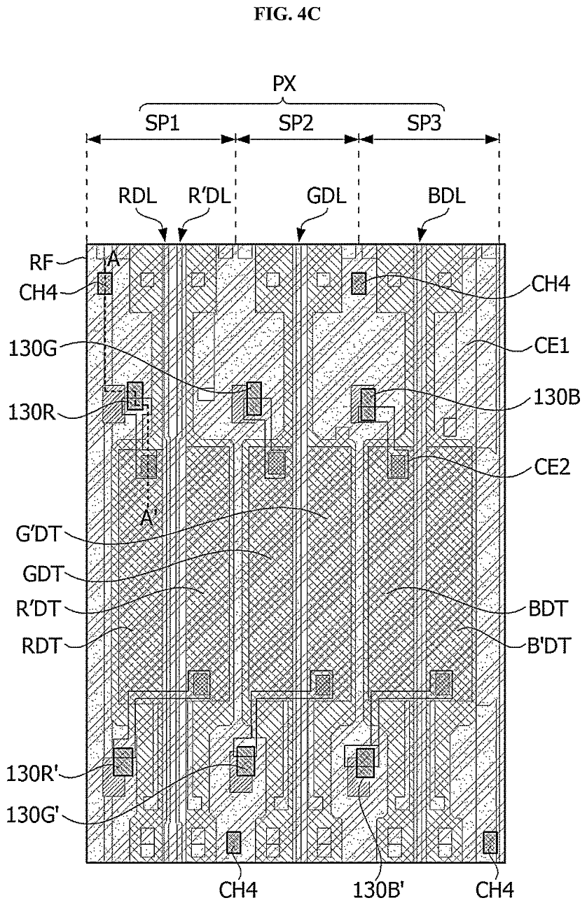

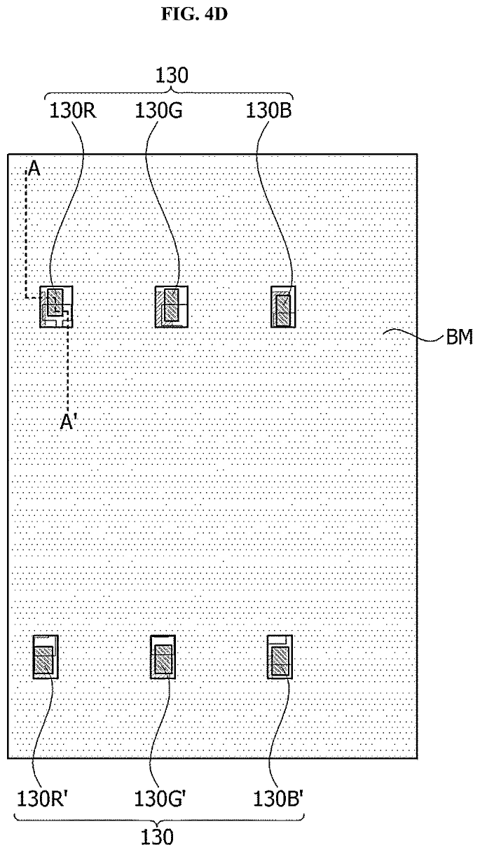

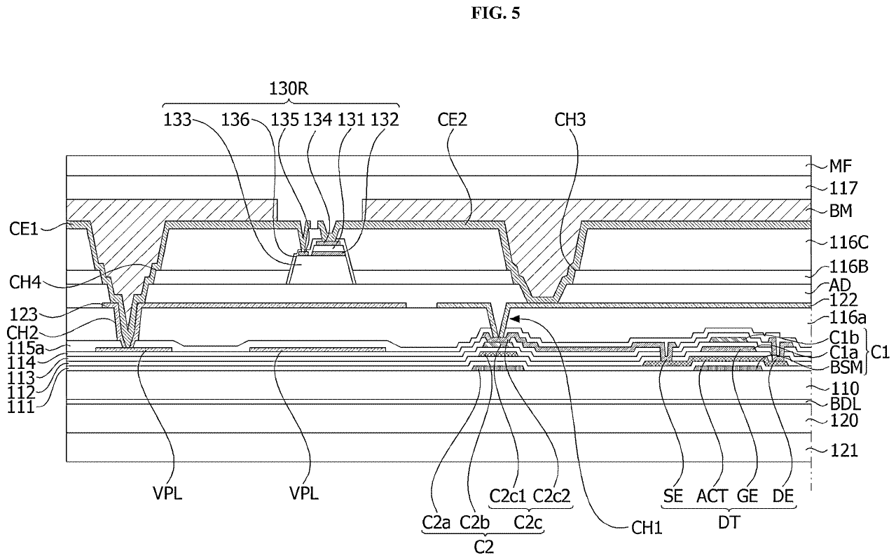

The sub-pixels SP of the pixel regions UPA will be described in more detail with reference to FIGS. 4A to 4D and FIG. 5.

The display region AA may include a light-emitting region and a non-light-emitting region on the first substrate 110. The light-emitting region may be a region where the light-emitting elements are disposed and thus light is emitted, and the non-light-emitting region may be a region where the light-emitting elements are not disposed.

A plurality of sub-pixels SP forming one pixel PX are disposed in one pixel region UPA. For example, the plurality of sub-pixels SP may include a first sub-pixel SP1, a second sub-pixel SP2, and a third sub-pixel SP3 which emit light of different colors. A red light-emitting element 130R may be disposed in the first sub-pixel SP1, a green light-emitting element 130G may be disposed in the second sub-pixel SP2, and a blue light-emitting element 130B may be disposed in the third sub-pixel SP3.

Referring to FIG. 4A, as described above, a plurality of lines which supply various signals to a plurality of sub-pixels SP1, SP2, and SP3 are disposed in the plurality of pixel regions UPA of the first substrate 110. For example, a plurality of data lines RDL, R′DL, GDL, and BDL extending in the column direction and high-potential power lines VPL which transmit signals from the high-potential power pads (VP1 in FIG. 3) may be disposed on the first substrate 110.

In the present disclosure, although an example in which the high-potential power lines VPL are disposed in the pixel region in the column direction and connected to the light-emitting elements is described, the low-potential power lines connected to the low-potential power pads (VP2 in FIG. 3) may be disposed in the pixel region in the column direction, but are not limited thereto.

The high-potential power lines VPL may be disposed between the sub-pixels SP and formed wider than the plurality of data lines RDL, R′DL, GDL, and BDL. The high-potential power lines VPL may be formed as wide as possible to minimize a voltage drop and a voltage deviation of the high-potential voltage.

A non-light-emitting region of each of the sub-pixels SP1, SP2, and SP3 may include a driving circuit unit, and may include at least two light-emitting elements.

In order to drive at least two light-emitting elements, the driving circuit unit of each of the sub-pixels SP1, SP2, and SP3 may include main light-emitting circuit units RDT, GDT, and BDT and auxiliary light-emitting circuit units R′DT, G′DT, and B′DT.

A red main light-emitting circuit unit RDT and a red auxiliary light-emitting circuit unit R′DT may respectively include a first red data line RDL and a second red data line R′DL in the red sub-pixel SP1, a green sub-pixel SP2 may apply signals to a green main light-emitting circuit unit GDT and a green auxiliary light-emitting circuit unit G′DT through one green data line GDL, and a blue sub-pixel SP3 may apply signals to a blue main light-emitting circuit unit BDT and a blue auxiliary light-emitting circuit unit B′DT through one blue data line BDL.

The driving circuit unit may include first contact holes CH1 for electrical connection between the light-emitting elements and the transistors of the driving circuit unit.

The high-potential power lines VPL may have different widths for each region in order to be disposed as widely as possible in regions except for a region where the driving circuit unit is disposed and a contact region where the driving circuit unit and lower lines are connected.

The high-potential power line VPL may include a first region and a second region, a width L1 of the first region and a width L2 of the second region may be different from each other, and the width L1 of the first region may be wider than the width L2 of the second region.

Further, the high-potential power line VPL may further include a third region, and a width L3 of the third region may be wider than the width L2 of the second region and narrower than the width L1 of the first region.

The high-potential power lines VPL may be formed in the same process as the plurality of data lines RDL, R′DL, GDL, and BDL.

The high-potential power lines VPL and the plurality of data lines RDL, R′DL, GDL, and BDL may be formed of opaque metal materials, and may include one or more among copper (Cu), aluminum (Al), molybdenum (Mo), nickel (Ni), titanium (Ti), chromium (Cr), and the like or may be formed of an alloy thereof, but are not limited thereto.

Further, a light blocking layer BSM, a semiconductor layer ACT, and insulating layers may be disposed under the high-potential power lines VPL and the plurality of data lines RDL, R′DL, GDL, and BDL.

Referring to FIG. 4B, metal layers may be disposed on the driving circuit units and the high-potential power lines VPL. In this case, the metal layers may be spaced apart from each other and composed of first electrodes 122 second electrodes 123.

The first electrodes 122 are electrically connected to the driving circuit units through the first contact holes CH1, and the second electrodes 123 may be electrically connected to the light-emitting elements through second contact holes CH2.

Third contact holes CH3 may be disposed to overlap the region where the first contact holes CH1 are disposed. The light-emitting elements may be electrically connected to the first electrodes 122 and the driving circuit units through the third contact holes CH3.

The first electrodes 122 may overlap the electrodes of the driving circuit units to form capacitors. In order to form sufficient capacitors, the first electrode may have an area overlapping the entire driving circuit unit.

After disposing the first electrodes 122 and the second electrodes 123, inspection for detecting defects of the transistors of the driving circuit unit and repair thereof may be performed.

By applying a voltage to the driving circuit unit and inspecting the defects, lines of the defective transistors in the driving circuit unit may be cut or welded with laser irradiation to repair the transistors.

Since the first electrodes 122 and the second electrodes 123 are formed of transparent materials, defects of the transistors in the driving circuit unit disposed under the first electrodes 122 may be easily checked during defect detection inspection.

Since the first electrodes 122 and the second electrodes 123 are formed of transparent materials, when the light-emitting elements are disposed thereafter, the light-emitting elements may be disposed in a region overlapping the high-potential power lines VPL formed of an opaque metal.

An opaque layer may be disposed at the bottom of the light-emitting elements to improve luminance efficiency through reflection of light from the bottom. Since the high-potential power lines VPL are formed of an opaque material and the widths of the first region and the third region are wide, luminance efficiency may be improved by disposing the light-emitting elements in the first region and the third region.

Further, since the first electrodes 122 and the second electrodes 123 disposed over large areas on the substrate 110 are formed of transparent materials, reflection visibility by a large-area opaque metal layer which may occur when the display device is not driven may be reduced.

Referring to FIG. 4C, since main light-emitting elements 130R, 130G, and 130B and auxiliary light-emitting elements 130R′, 130G′, and 130B′ may be disposed in the first region and the third region of the high-potential power lines (VPL in FIG. 4B), a light-emitting region may be formed. The light-emitting elements may overlap the power lines.

First connection electrodes CE1 and second connection electrodes CE2 may be disposed on the first electrodes 122, the second electrodes 123, the main light-emitting elements 130R, 130G, and 130B, and the auxiliary light-emitting elements 130R′, 130G′, and 130B′.

The first connection electrodes CE1 may be electrically connected to the high-potential power lines VPL through fourth contact holes CH4 to apply a high-potential voltage to the light-emitting elements.

The first connection electrodes CE1 may be disposed on the entire surface of the light-emitting region on the first substrate 110 except for a region of the second connection electrodes CE2, and may be disposed to be spaced apart from each other for each of sub-pixels SP1, SP2, and SP3, but are not limited thereto.

The second connection electrodes CE2 may be connected to the driving circuit units through the first contact holes (CH1 in FIG. 4A) and the third contact holes (CH3 in FIG. 4B) to apply a low-potential voltage to the light-emitting elements, and depending on the design, the first connection electrodes CE1 may transmit a low-potential voltage to the light-emitting elements, and the second connection electrodes CE2 may transmit a high-potential voltage to the light-emitting elements.

Further, for each of the sub-pixels SP1, SP2, and SP3, for example, the red sub-pixel SP1 may be connected to the driving circuit unit through the first contact hole (CH1 in FIG. 4A) and the third contact hole (CH3 in FIG. 4B) to transmit a high-potential voltage to the light-emitting elements and allow the second connection electrode CE2 to transmit a low-potential voltage to the light-emitting elements, and the green sub-pixel SP2 and the blue sub-pixel SP3 may be connected to the driving circuit units through the first contact holes (CH1 in FIG. 4A) and the third contact holes (CH3 in FIG. 4B) to transmit a low-potential voltage to the light-emitting elements and allow the second connection electrodes CE2 to transmit a high-potential voltage to the light-emitting elements, but are not limited thereto.

One or more fourth contact holes CH4 may be disposed on each high-potential power line VPL in FIG. 4B, and may be disposed in each pixel PX or in only one pixel PX among several pixels depending on the disposition of the second connection electrodes CE2, but are not limited thereto.

Referring to FIG. 4D, in order to prevent the deterioration of the driving circuit unit by an external light source, a black matrix BM may be disposed on the substrate except for the regions where the light-emitting elements are disposed.

Accordingly, the deterioration of the driving circuit may be prevented and light interference between sub-pixels SP emitting different colors may be prevented.

FIG. 5 is a cross-sectional view of the display device according to one example embodiment of the present disclosure.

Referring to FIG. 5, the display panel PN includes a first substrate 110. The first substrate 110 is a substrate which supports components disposed on the display device 100 and may be an insulating substrate. A plurality of pixels PX may be formed on the first substrate 110 to display an image. For example, the first substrate 110 may be formed of glass or resin. Further, the first substrate 110 may be formed of a polymer or plastic. In some embodiments, the first substrate 110 may be formed of a plastic material having flexibility.

A light blocking layer BSM may be disposed on the first substrate 110. The light blocking layer BSM may minimize a leakage current by blocking light incident on active layers ACT of a plurality of transistors. For example, the light blocking layer BSM may be disposed under the active layer ACT of a driving transistor DT to block light incident on the active layer ACT.

When the light is irradiated to the active layer ACT, leakage current may occur and the reliability of the transistor may deteriorate. Accordingly, the reliability of the driving transistor DT may be improved by disposing the light blocking layer BSM which blocks light on the first substrate 110. The light blocking layer BSM may be formed of an opaque conductive material, for example, copper (Cu), aluminum (Al), molybdenum (Mo), nickel (Ni), titanium (Ti), chromium (Cr), or the like or an alloy thereof, but is not limited thereto.

A buffer layer 111 is disposed on the light blocking layer BSM. The buffer layer 111 may reduce the penetration of moisture or impurities through the first substrate 110. The buffer layer 111 may be composed of, for example, a single layer or multiple layers of silicon oxide (SiOₓ) or silicon nitride (SiNₓ), but is not limited thereto. However, the buffer layer 111 may be omitted depending on the type of first substrate 110 or the type of thin film transistor, but is not limited thereto.

Further, although not shown in the drawings, an additional buffer layer may be disposed between the first substrate 110 and the light blocking layer BSM. The additional buffer layer may be composed of, for example, a single layer or multiple layers of silicon oxide (SiOₓ) or silicon nitride (SiNₓ) to reduce the penetration of moisture or impurities through the first substrate 110 in the same manner as the above-described buffer layer 111, but is not limited thereto.

The driving transistor DT including the active layer ACT, a gate electrode GE, a source electrode SE, and a drain electrode DE is disposed on the buffer layer 111.

First, the active layer ACT of the driving transistor DT is disposed on the buffer layer 111. The active layer ACT may be formed of a semiconductor material such as an oxide semiconductor, amorphous silicon, polysilicon, or the like but is not limited thereto. Further, although not shown in the drawings, other transistors other than the driving transistor DT, such as a switching transistor, a sensing transistor, an emission control transistor, and the like may be additionally disposed, and the active layers of these transistors may also be formed of a semiconductor material such as an oxide semiconductor, amorphous silicon, polysilicon, or the like, but are not limited thereto. Further, the active layers of transistors included in the pixel circuit, such as the driving transistor DT, the switching transistor, the sensing transistor, the emission control transistor, and the like may be formed of the same material or may be formed of different materials.

A gate insulating layer 112 is disposed on the active layer ACT. The gate insulating layer 112 is an insulating layer for electrically insulating the active layer ACT and the gate electrode GE, and may be composed of a single layer or multiple layers of silicon oxide (SiOₓ) or silicon nitride (SiNₓ), but is not limited thereto.

The gate electrode GE is disposed on the gate insulating layer 112. The gate electrode GE may be formed of a conductive material, for example, copper (Cu), aluminum (Al), molybdenum (Mo), nickel (Ni), titanium (Ti), chromium (Cr), or the like or an alloy thereof, but is not limited thereto.

A first interlayer insulating layer 113 and a second interlayer insulating layer 114 are disposed on the gate electrode GE. Contact holes are formed in the first interlayer insulating layer 113 and the second interlayer insulating layer 114 so that the source electrode SE and the drain electrode DE are each connected to the active layer ACT. The first interlayer insulating layer 113 and the second interlayer insulating layer 114 are insulating layers for protecting lower configurations, and may be composed of a single layer or multiple layers of silicon oxide (SiOₓ) or silicon nitride (SiNₓ), but are not limited thereto.

The source electrode SE and the drain electrode DE electrically connected to the active layer ACT are disposed on the second interlayer insulating layer 114. The source electrode SE is connected to a second capacitor C2 and a first electrode layer 134 of the light-emitting element 130, and the drain electrode DE is connected to other components of the pixel circuit. The source electrode SE and the drain electrode DE may be formed of a conductive material, for example, copper (Cu), aluminum (Al), molybdenum (Mo), nickel (Ni), titanium (Ti), chromium (Cr), or the like or an alloy thereof, but are not limited thereto.

Next, a first capacitor C1 is disposed on the gate insulating layer 112. The first capacitor C1 includes a 1-1 capacitor electrode C1a and a 1-2 capacitor electrode C1b.

First, the 1-1 capacitor electrode C1a is disposed on the gate insulating layer 112. The 1-1 capacitor electrode C1a may be integrated with the gate electrode GE of the driving transistor DT.

The 1-2 capacitor electrode C1b is disposed on the first interlayer insulating layer 113. The 1-2 capacitor electrode C1b is disposed to overlap the 1-1 capacitor electrode C1a with the first interlayer insulating layer 113 interposed therebetween.

Accordingly, the first capacitor C1 may be connected to the gate electrode GE of the driving transistor DT and may maintain a voltage of the gate electrode GE of the driving transistor DT for a certain period of time.

Next, the second capacitor C2 is disposed on the first substrate 110. The second capacitor C2 includes a 2-1 capacitor electrode C2a which is a lower capacitor electrode, a 2-2 capacitor electrode C2b which is a middle capacitor electrode, and a 2-3 capacitor electrode C2c which is an upper capacitor electrode.

The 2-1 capacitor electrode C2a is disposed on the first substrate 110. The 2-1 capacitor electrode C2a may be disposed on the same layer and formed of the same material as the light blocking layer BSM.

The 2-2 capacitor electrode C2b is disposed on the buffer layer 111 and the gate insulating layer 112. The 2-2 capacitor electrode may be disposed on the same layer and formed of the same material as the gate electrode GE.

The 2-3 capacitor electrode C2c is disposed on the first interlayer insulating layer 113. The 2-3 capacitor electrode C2c may be composed of a first layer C2c1 and a second layer C2c2. The first layer C2c1 of the 2-3 capacitor electrode C2c may be formed of the same material as the 1-2 capacitor electrode C1b in the same layer. The first layer C2c1 may be disposed to overlap the 2-1 capacitor electrode C2a and the 2-2 capacitor electrode C2b with the first interlayer insulating layer 113 interposed therebetween.

The second layer C2c2 of the 2-3 capacitor electrode C2c is disposed on the second interlayer insulating layer 114. The second layer C2c2 is a portion extending from the source electrode SE of the driving transistor DT and may be connected to the first layer C2c1 through a contact hole in the second interlayer insulating layer 114.

Accordingly, the second capacitor C2 may be electrically connected between the source electrode SE of the driving transistor DT and the light-emitting element 130, and thus may increase the capacitance inherent in the light-emitting element 130 and allow light of higher luminance to be emitted from light-emitting element 130.

A first passivation layer 115a is disposed on the driving transistor DT, the first capacitor C1, and the second capacitor C2. The first passivation layer 115a is an insulating layer for protecting the configurations under the first passivation layer 115a, and may be formed of an inorganic material such as silicon oxide (SiOₓ) or silicon nitride (SiNₓ), but is not limited thereto.

A first planarization layer 116a is disposed on the first passivation layer 115a. The first planarization layer 116a may planarize an upper portion of the pixel circuit including the driving transistor DT. The first planarization layer 116a may be composed of a single layer or multiple layers, and may be formed of, for example, benzocyclobutene or acryl-based organic materials, but is not limited thereto.

A first contact hole CH1 and a second contact hole CH2 may be formed in the first passivation layer 115a and the first planarization layer 116a.

The first contact hole CH1 may expose a portion of the source electrode SE of the driving transistor DT.

The second contact hole CH2 may expose a portion of the high-potential power line VPL.

A first electrode 122 and a second electrode 123, which are metal layers, may be disposed on the first planarization layer 116a.

The first electrode 122 and the second electrode 123 may be formed through the same process using the same material.

The first electrode 122 and the second electrode 123 may be formed of a transparent conductive material, for example, indium tin oxide (ITO) or indium zinc oxide (IZO).

The first electrode 122 may be electrically connected to the driving transistor DT through the first contact hole CH1, and the second electrode 123 may be a connection line electrically connecting the light-emitting element and the high-potential power line VPL through the second contact hole CH2.

The first electrode 122 may overlap the electrodes of the driving circuit unit to form capacitors. In order to form sufficient capacitors, the first electrode may overlap the driving circuit unit and the high-potential power line VPL.

Further, according to the properties of the display device, the first electrode 122 may electrically connect the high-potential power line VPL and the light-emitting element, and the second electrode 123 may electrically connect the driving transistor DT and the light-emitting element.

An adhesive layer AD is disposed on the first planarization layer 116a. The adhesive layer AD may be disposed between the first electrode 122 and the second electrode 123 and the plurality of light-emitting elements and formed on the entire surface of the first substrate 110 to fix the light-emitting elements 130 disposed on the adhesive layer AD. The adhesive layer AD may be formed of a photocurable adhesive material which may be cured by light. For example, the adhesive layer AD may be formed of an acrylic-based material containing a photosensitive agent, but is not limited thereto. The adhesive layer AD may be formed on the entire surface of the first substrate 110 except for the pad region where the first pad electrodes PAD1 will be disposed.

A plurality of light-emitting elements (130 in FIG. 4D) are respectively disposed in the plurality of sub-pixels (SP in FIG. 2B) on the adhesive layer AD. The light-emitting elements 130 are elements which emit light by current, and may include a red light-emitting element (130R in FIG. 4D) which emits red light, a green light-emitting element (130G in FIG. 4D) which emits green light, and a blue light-emitting element (130B in FIG. 4D) which emits blue light, and light of various colors including white may be implemented by a combination thereof. For example, the light-emitting element 130 may be a light-emitting diode (LED) or micro-LED, but is not limited thereto.

Meanwhile, the light-emitting elements 130 respectively disposed in the plurality of sub-pixels SP may have different structures.

In the light-emitting element 130, the red light-emitting element 130R and an auxiliary red light-emitting element (130R′ in FIG. 4C) disposed in the first sub-pixel (SP1 in FIG. 4C), the green light-emitting element 130G and an auxiliary green light-emitting element (130G′ in FIG. 4C) disposed in the second sub-pixel (SP2 in FIG. 4C), and the blue light-emitting element 130B and an auxiliary blue light-emitting element (130B′ in FIG. 4C) disposed in the third sub-pixel (SP3 in FIG. 4C) may be disposed.

Since one or more light-emitting elements are disposed in each sub-pixel SP, when one light-emitting element is defective, the light-emitting efficiency of the other light-emitting element may be improved to prevent the light-emitting efficiency in the pixel PX from being reduced.

The red light-emitting element 130R and the auxiliary red light-emitting element 130R′ of the first sub-pixel SP1 may be respectively connected to the data lines (RDL and R′DL in FIG. 4C) and the driving transistors (RDT and R′DT in FIG. 4C) to be individually driven.

The green light-emitting element 130G and the auxiliary green light-emitting element 130G′ of the second sub-pixel SP2 may be connected to one green data line (GDL in FIG. 4C) to be driven in parallel.

The blue light-emitting element 130B and the auxiliary blue light-emitting element 130B′ of the third sub-pixel SP3 may be connected to one blue data line (BDL in FIG. 4C) to be driven in parallel.

For example, the red light-emitting element 130R includes a first semiconductor layer 131, a light-emitting layer 132, a second semiconductor layer 133, a first electrode layer 134, a second electrode layer 135, and an encapsulation film 136.

Referring to FIG. 5, for example, when the light-emitting element (130 in FIG. 4D) is the red light-emitting element 130R, the second semiconductor layer 133 may be disposed on the adhesive layer AD, and the second semiconductor layer 133 may be disposed under the first semiconductor layer 131.

In the case of the red light-emitting element 130R, the light-emitting layer 132 is disposed between the first semiconductor layer 131 and the second semiconductor layer 133. The light-emitting layer 132 may emit light by receiving holes and electrons from the first semiconductor layer 131 and the second semiconductor layer 133. The light-emitting layer 132 may be formed in a single-layer or multi-quantum well (MQW) structure, and formed of, for example, indium gallium nitride (InGaN) or gallium nitride (GaN), but is not limited thereto.

In the case of the red light-emitting element 130R, the second electrode layer 135 is disposed on the second semiconductor layer 133. The second semiconductor layer 133 is an electrode for electrically connecting the high-potential power line VLP and the second semiconductor layer 133.

In the case of the red light-emitting element 130R, the second semiconductor layer 133 may be a semiconductor layer doped with p-type impurities such as magnesium, zinc (Zn), and beryllium (Be), and the second electrode layer 135 may be a cathode.

In the case of the red light-emitting element 130R, the second electrode layer 135 may be disposed on an upper surface of the second semiconductor layer 133 exposed from the light-emitting layer 132 and the first semiconductor layer 131. The second electrode layer 135 may be formed of a conductive material, for example, a transparent conductive material such as indium tin oxide (ITO), indium zinc oxide (IZO), or the like or an opaque conductive material such as titanium (Ti), gold (Au), silver (Ag), copper (Cu), or an alloy thereof, but is not limited thereto.

In the case of the red light-emitting element 130R, the first electrode layer 134 is disposed on the first semiconductor layer 131. The first electrode layer 134 may be disposed on an upper surface of the first semiconductor layer 131. The first electrode layer 134 is an electrode for electrically connecting the driving transistor DT and the first semiconductor layer 131. In this case, the first semiconductor layer 131 may be a semiconductor layer doped with n-type impurities such as silicon (Si), germanium, and tin (Sn), and the first electrode layer 134 may be an anode. The first electrode layer 134 may be formed of a conductive material, for example, a transparent conductive material such as indium tin oxide (ITO), indium zinc oxide (IZO), or the like or an opaque conductive material such as titanium (Ti), gold (Au), silver (Ag), copper (Cu), or the alloy thereof, but is not limited thereto.

In the case of the red light-emitting element 130R, the encapsulation film 136 surrounding the first semiconductor layer 131, the light-emitting layer 132, the second semiconductor layer 133, the first electrode layer 134, and the second electrode layer 135 is disposed.

The encapsulation film 136 may be formed of an insulating material and protect the first semiconductor layer 131, the light-emitting layer 132, and the second semiconductor layer 133. Further, since a contact hole which exposes the first electrode layer 134 and the second electrode layer 135 is formed in the encapsulation film 136, the first connection electrode CE1, the second connection electrode CE2, the first electrode layer 134, and the second electrode layer 135 may be electrically connected.

The auxiliary red light-emitting element 130R′ may also be formed and disposed in the same structure as the red light-emitting element 130R. Accordingly, repeated description will be omitted.

The green light-emitting element (130G in FIG. 4D), the auxiliary green light-emitting element (130G′ in FIG. 4D), the blue light-emitting element (130B in FIG. 4D), and the auxiliary blue light-emitting element (130B′ in FIG. 4D) may have different structures from the red light-emitting element 130R. A first semiconductor layer may be disposed on the adhesive layer AD, and a second semiconductor layer may be disposed on the first semiconductor layer. In this case, a first electrode layer may be disposed on the first semiconductor layer. The first electrode layer may be an electrode for electrically connecting the driving transistor DT and the first semiconductor layer, the first semiconductor layer may be a semiconductor layer doped with n-type impurities, and the first electrode layer may be a cathode.

Further, a second electrode layer may be disposed on the second semiconductor layer. The second electrode layer may be disposed on an upper surface of the second semiconductor layer. The second electrode layer may be an electrode for electrically connecting the high-potential power line and the second semiconductor layer, the second semiconductor layer may be a semiconductor layer doped with p-type impurities, and the second electrode layer may be an anode.

All of the red, green, and blue light-emitting elements 130R, 130G and 130B may have the same structure or have different structures, but are not limited thereto.

The red light-emitting element 130R is disposed on the adhesive layer AD, and a second planarization layer 116b and a third planarization layer 116c are disposed.

The second planarization layer 116b may overlap portions of side surfaces of the plurality of light-emitting elements 130 to fix and protect the plurality of light-emitting elements 130. The second planarization layer 116b may be formed using a halftone mask. Accordingly, the second planarization layer 116b may be formed to have a step.

Specifically, in the second planarization layer 116b, a portion disposed relatively adjacent to the light-emitting element 130 may be formed to have a relatively thin thickness, and a portion disposed relatively far from the light-emitting element 130 may be formed to have a relatively thick thickness.

The portion of the second planarization layer 116b disposed adjacent to the light-emitting element 130 may be disposed to surround the light-emitting element 130 and come into contact with a side surface of the light-emitting element 130. Accordingly, in a process of separating the light-emitting element 130 from a wafer and transferring the light-emitting element 130 to the display panel PN, a portion where the encapsulation film 136, which protects a side surface of the first semiconductor layer 131 of the light-emitting element 130, is torn off may be covered by the second planarization layer 116b. Accordingly, it is possible to prevent contact and short circuit defects between the connection electrodes CE1 and CE2 and the first semiconductor layer 131 in the future.

The third planarization layer 116c may be formed to cover the second planarization layer 116b and an upper portion of the light-emitting element 130, and a contact hole through which the first electrode layer 134 and the second electrode layer 135 of the light-emitting element 130 are exposed may be formed. Since the first electrode layer 134 and the second electrode layer 135 of the light-emitting element 130 are exposed from the third planarization layer 116c and the third planarization layer 116c is partially disposed in a region between the first electrode layer 134 and the second electrode layer 135, short circuit defects may be reduced. The second planarization layer 116b and the third planarization layer 116c may be composed of a single layer or multiple layers, and may be formed of, for example, a photoresist or an acryl-based organic material, but are not limited thereto.

The first connection electrode CE1 and the second connection electrode CE2 are disposed on the third planarization layer 116c. The first connection electrode CE1 is an electrode which electrically connects the second electrode layer 135 of the light-emitting element 130 and the high-potential power line VL1.

The first connection electrode CE1 may be in contact with the second electrode 123 through a fourth contact hole CH4 formed in the adhesive layer AD, the second planarization layer 116b, the third planarization layer 116c to be electrically connected to the high-potential power line VPL.

The second connection electrode CE2 may be in contact with the first electrode 122 through a third contact hole CH3 formed in the adhesive layer AD, the second planarization layer 116b, and the third planarization layer 116c to be electrically connected to the driving transistor DT.

The first connection electrode CE1 and the second connection electrode CE2 may be formed of a transparent conductive material, for example, indium tin oxide (ITO), indium zinc oxide (IZO), or the like, but are not limited thereto.

The black matrix BM may be disposed on the first connection electrode CE1 and the second connection electrode CE2. The black matrix BM may be spaced a certain distance from the light-emitting element 130 and disposed on the entire substrate except for the light-emitting region. This structure may prevent the deterioration of the transistors of the driving circuit unit by an external light source.

The black matrix BM may be formed of an opaque material, for example, a black resin, but is not limited thereto.

The black matrix BM may be formed in the third contact hole CH3 and the fourth contact hole CH4 of the third planarization layer 116c and the second planarization layer 116b and may be disposed up to a lower portion of the light-emitting element 130, that is, a position lower than the light-emitting element 130.

A first protective layer 117 is disposed on the first connection electrode CE1, the second connection electrode CE2, and the black matrix BM. The first protective layer 117 is a layer for protecting the configurations under the first protective layer 117 and, for example, may cover at least a portion of the light-emitting element 130. The first protective layer 117 may be composed of a single layer or multiple layers of light-transmissive epoxy, silicon oxide (SiOₓ), or silicon nitride (SiNₓ), but is not limited thereto.

A cover substrate may be disposed on the first protective layer 117 to protect layers and elements. The cover substrate may be composed of a single layer or multi-layer structure of an organic material or a material such as polyimide, polyethylene terephthalate, polyethylene naphthalate, polycarbonate, polyethersulfone, polyarylate, polysulfone, a cyclic-olefin copolymer, or the like, but is not limited thereto.

A touch electrode for touch driving may be additionally disposed on the first protective layer 117. The touch electrode may be electrically connected to the driving circuit unit and electrically connected to a touch driving circuit IC outside the display region AA.

A color filter may be further disposed and an optical film MF may be disposed on the first protective layer 117 or in a region overlapping the light-emitting unit. The optical film MF may be a functional film which protects the display device 100 and implements a relatively higher-quality image. For example, the optical film MF may include a shatterproof film, an anti-glare film, an anti-reflective film, a low-reflection film, a luminance enhancement film (an OLED transmittance controllable film), a polarization plate, or the like, but is not limited thereto.

Meanwhile, an adhesive layer may be additionally disposed between the optical film MF and the first protective layer 117.

A second substrate 120 is disposed under the first substrate 110. The second substrate 120 is a substrate which supports components disposed under the display device 100, and may be an insulating substrate. For example, the second substrate 120 may be formed of glass or resin. Further, the second substrate 120 may be formed by including a polymer or plastic. The second substrate 120 may be formed of the same material as the first substrate 110. In some embodiments, the second substrate 120 may be formed of a plastic material having flexibility.

A bonding layer BDL is disposed between the first substrate 110 and the second substrate 120. The bonding layer BDL may be formed of a material which may be cured through various curing methods to bond the first substrate 110 and the second substrate 120. The bonding layer BDL may be disposed only in a partial region between the first substrate 110 and the second substrate 120, and may be disposed in an entire region.

Referring to FIG. 2A again, the plurality of second pad electrodes PAD2 are disposed on the rear surface of the second substrate 120. The plurality of second pad electrodes PAD2 are electrodes which transmit signals to the plurality of side lines SRL, the plurality of first pad electrodes PAD1 on the first substrate 110, and the plurality of lines from driving components disposed on the rear surface of the second substrate 120. The plurality of second pad electrodes PAD2 may be electrically connected to the side lines SRL which are disposed at end portions of the second substrate 120 in the non-display region NA and cover the end portions of the second substrate 120.

A side insulating layer which covers the plurality of side lines SRL is disposed. The side insulating layer may be formed to cover the side lines SRL on an upper surface of the first substrate 110, a side surface of the first substrate 110, a side surface of the second substrate 120, and the rear surface of the second substrate 120.

Meanwhile, when the plurality of side lines SRL are formed of a metal material, a problem in that external light is reflected from the plurality of side lines SRL or light emitted from the light-emitting elements 130 is reflected from the plurality of side lines SRL and is visible to a user may occur. Accordingly, the side insulating layer is configured to include a black material, thereby suppressing external light reflection. For example, the side insulating layer may be formed by a pad printing method using an insulating material containing a black material, for example, black ink.

Further, although not shown in the drawings, driving components including a plurality of flexible films and a printed circuit board may be disposed on the rear side of the second substrate 120. The plurality of flexible films are components which supply signals to a plurality of sub-pixels SP by disposing various components such as a data driver IC on a flexible base film. The printed circuit board is a component which is electrically connected to the plurality of flexible films and supplies signals to a driver IC. Various components may be disposed on the printed circuit board to supply various signals to the driver IC.

Various examples and aspects of the present disclosure are described below. These are provided as examples, and do not limit the scope of the present disclosure.

A display device according to one or more example embodiments of the present disclosure comprises a display region and a non-display region disposed on a substrate, a pixel including a plurality of sub-pixels disposed in the display region, and a power line disposed between each of the plurality of sub-pixels, wherein a light-emitting element is disposed on the power line, the light-emitting element is for being electrically connected to a first connection electrode, each sub-pixel of the plurality of sub-pixels includes a plurality of transistors, and a second connection electrode is connected to a driving transistor among the plurality of transistors.

The power line may include a first region and a second region, and a width of the first region and a width of the second region are different from each other.

The width of the first region may be wider than the width of the second region; and the light-emitting element may be disposed in the first region of the power line.

The power line may further include a third region, and a width of the third region is wider than the width of the second region and narrower than the width of the first region.

Each sub-pixel of the plurality of sub-pixels includes at least two light-emitting elements, and the at least two light-emitting elements are disposed in the first region and the third region of the power line.

The power line may be electrically connected to the light-emitting element through a connection line.

A metal layer may be disposed between the second connection electrode and the plurality of transistors.

The metal layer may be disposed between the power line and the light-emitting element.

The metal layer may comprise a transparent metal material.

A black matrix may be disposed on an entire surface of the display region except for an area in which the light-emitting element is disposed and is spaced a certain distance from the light-emitting element.

The plurality of transistors may be disposed in the second region.

A display device according to one or more example embodiments of the present disclosure comprise a substrate, a display region, and a non-display region, wherein the display region includes a light-emitting region and a non-light-emitting region, a transistor is disposed in the non-light-emitting region, a power line is disposed in the light-emitting region and the non-light-emitting region, a first electrode is disposed on the transistor and the power line, a light-emitting element is disposed on the first electrode, and the light-emitting element overlaps the power line.

The first electrode may be electrically connected to the transistor.

The transistor may include a semiconductor layer, source and drain electrodes, and a gate electrode.

The source and drain electrodes and the power line may be disposed on a same layer.

The power line may be disposed to extend in a column direction, and includes a first region, a second region, and a third region in the column direction.

In the power line, a width of the first region is wider than a width of the second region and is wider than a width of the third region.

The width of the third region may be wider than the width of the second region.

The light-emitting element may be disposed in at least one of the first region and the third region.

The transistor may be disposed in the second region which is between the first region and the third region of the power line.

The effects of the present disclosure are not limited to the effects mentioned above, and other effects not mentioned may be clearly understood by those skilled in the art from the description of the claims.

While the embodiments have been described in detail above with reference to the accompanying drawings, the present disclosure is not necessarily limited to these embodiments, and various changes and modifications may be made without departing from the technical spirit of the present invention. Accordingly, the embodiments disclosed herein are to be considered descriptive and not restrictive of the technical spirit of the present disclosure, and the scope of the technical spirit of the present disclosure is not limited by these embodiments. Therefore, the above-described embodiments should be understood to be examples and not limiting in any aspect. The scope of protection of the present disclosure should be construed based on the following claims, and all technical features within the scope of equivalents thereof should be construed as being included within the scope of the present disclosure.

What is claimed is:

1. A display device, comprising:
a display region and a non-display region disposed on a substrate;
a pixel including a plurality of sub-pixels disposed in the display region; and
a power line disposed between each of the plurality of sub-pixels,
wherein:
a light-emitting element is disposed on the power line;
the light-emitting element is for being electrically connected to a first connection electrode;
each sub-pixel of the plurality of sub-pixels includes a plurality of transistors; and
a second connection electrode is connected to a driving transistor among the plurality of transistors.

2. The display device of claim 1, wherein:
the power line includes a first region and a second region; and
a width of the first region and a width of the second region are different from each other.

3. The display device of claim 2, wherein:
the width of the first region is wider than the width of the second region; and
the light-emitting element is disposed in the first region of the power line.

4. The display device of claim 3, wherein:
the power line further includes a third region; and
a width of the third region is wider than the width of the second region and narrower than the width of the first region.

5. The display device of claim 4, wherein:
each sub-pixel of the plurality of sub-pixels includes at least two light-emitting elements; and
the at least two light-emitting elements are disposed in the first region and the third region of the power line.

6. The display device of claim 2, wherein the power line is for being electrically connected to the light-emitting element through a connection line.

7. The display device of claim 1, wherein a metal layer is disposed between the second connection electrode and the plurality of transistors.

8. The display device of claim 7, wherein the metal layer is disposed between the power line and the light-emitting element.

9. The display device of claim 8, wherein the metal layer comprises a transparent metal material.

10. The display device of claim 1, wherein a black matrix is disposed on an entire surface of the display region except for an area in which the light-emitting element is disposed and is spaced a certain distance from the light-emitting element.

11. The display device of claim 2, wherein the plurality of transistors are disposed in the second region.

12. A display device, comprising:
a substrate;
a display region; and
a non-display region,
wherein:
the display region includes a light-emitting region and a non-light-emitting region;
a transistor is disposed in the non-light-emitting region;
a power line is disposed in the light-emitting region and the non-light-emitting region;
a first electrode is disposed on the transistor and the power line;
a light-emitting element is disposed on the first electrode; and
the light-emitting element overlaps the power line.

13. The display device of claim 12, wherein the first electrode is for being electrically connected to the transistor.

14. The display device of claim 12, wherein the transistor includes a semiconductor layer, source and drain electrodes, and a gate electrode.

15. The display device of claim 14, wherein the source and drain electrodes and the power line are disposed on a same layer.

16. The display device of claim 12, wherein the power line is disposed to extend in a column direction, and includes a first region, a second region, and a third region in the column direction.

17. The display device of claim 16, wherein, in the power line, a width of the first region is wider than a width of the second region and is wider than a width of the third region.

18. The display device of claim 17, wherein the width of the third region is wider than the width of the second region.

19. The display device of claim 17, wherein the light-emitting element is disposed in at least one of the first region and the third region.

20. The display device of claim 16, wherein the transistor is disposed in the second region which is between the first region and the third region of the power line.
